(19) United States
(12) Patent Application Publication
(10) Pub. No.: US 2025/0280596 A1
(43) Pub. Date: Sep. 4, 2025

(54) Semiconductor structure and manufacturing method thereof

(71) Applicant: UNITED MICROELECTRONICS CORP., Hsin-Chu City (TW)

(72) Inventors: Hsin-Hsien Chen, New Taipei City (TW); Kuo-Hsing Lee, Hsinchu County (TW)

(73) Assignee: UNITED MICROELECTRONICS CORP., Hsin-Chu City (TW)

(21) Appl. No.: 18/617,635

(22) Filed: Mar. 26, 2024

(30) Foreign Application Priority Data
Mar. 1, 2024 (TW) 113107453

(51) Int. Cl. H01L 27/088; H01L 21/8234; H01L 23/522

(52) U.S. Cl. CPC H10D 84/83; H01L 23/5226; H10D 84/0149; H10D 84/038

(57) ABSTRACT

The invention provides a semiconductor structure, which comprises a substrate, a first medium/high voltage device region and a low voltage device region are defined on the substrate, the first medium/high voltage device region comprises a first gate contact and a first source/drain contact, and the low voltage device region comprises two second source/drain contacts and a second gate contact, wherein the second gate contact is located between the two second source/drain contacts and directly contacts the two second source/drain contacts. A first conductive layer located in the first medium/high voltage device region, wherein the first conductive layer does not extend into the low voltage device region, and a second conductive layer located above the first conductive layer and spanning the first medium/high voltage device region and the low voltage device region.

### BACKGROUND OF THE INVENTION

### 1. Field of the Invention

The invention relates to the field of semiconductor manufacturing, in particular to a structure generated at the boundary of a medium/high voltage device region and a low voltage device region in the semiconductor manufacturing.

### 2. Description of the Prior Art

In the semiconductor process, the fineness of the nano-process is generally described in nanometers. For example, the 14-nanometer process means that the lowest line width that can be formed in the semiconductor process is 14 nanometers. With the progress of process technology, the line width of nano-process is gradually reduced.

However, even with the progress of nano-fabrication, not all devices are suitable for high-precision nano-fabrication. For example, when the size of the device does not match the precision of the nano-process, it will not only lead to the decline of the yield of the device, but also consume more costs. Therefore, in order to adapt to components with different sizes or precisions, different components will be formed by nano-processes with different precisions.

On one chip, there may be components with different precisions in different regions at the same time, which may be formed by nano-processes with different precisions. Therefore, at the boundary of these regions, various structural problems may easily occur.

### SUMMARY OF THE INVENTION

The invention provides a semiconductor structure, which comprises a substrate, wherein a first medium/high voltage device region and a low voltage device region are defined on the substrate, the first medium/high voltage device region comprises a first gate contact and a first source/drain contact, and the low voltage device region comprises two second source/drain contacts and a second gate contact, wherein the second gate contact is located between the two second source/drain contacts and directly contacts the two second source/drain contacts. A first conductive layer located in the first medium/high voltage device region and electrically connected to the first gate contact or the first source/drain contact, wherein the first conductive layer does not extend into the low voltage device region, and a second conductive layer located above the first conductive layer and spanning the first medium/high voltage device region and the low voltage device region, wherein the second conductive layer is electrically connected with the first conductive layer.

The invention also provides a method for manufacturing a semiconductor structure, which comprises providing a substrate, wherein a first medium/high voltage device region and a low voltage device region are defined adjacent to each other, the first medium/high voltage device region comprises a first gate contact and a first source/drain contact, and the low voltage device region comprises two second source/drain contacts and a second gate contact, wherein the second gate contact is located between the two second source/drain contacts and directly contacts the two second sources/drains. Forming a first conductive layer located in the first medium/high voltage device region and electrically connected to the first gate contact or the first source/drain contact, wherein the first conductive layer does not extend into the low voltage device region, and forming a second conductive layer located above the first conductive layer and spanning the first medium/high voltage device region and the low voltage device region, wherein the second conductive layer is electrically connected with the first conductive layer.

The applicant found that with the development of technology, the size of semiconductor devices is getting smaller and smaller, especially at the boundary of medium/high voltage device regions and low voltage device regions, various structural problems are easy to occur. For example, in the conventional 22 nm or 28 nm process, time dependent dielectric breakdown will not occur at the boundary of the medium/high voltage device region and the low voltage device region. However, as the process progresses below 17 nm, the conductive layer in the medium/high voltage device region is too close to the device in the low voltage device region, which may affect the quality of other devices due to time dependent dielectric breakdown. Therefore, the present invention aims at solving this problem, and specifically designs a semiconductor structure so that the first conductive layer in the medium/high voltage device region does not extend to the low voltage device region, and the second conductive layer in the medium/high voltage device region extends to the low voltage device region. Therefore, without changing the process conditions and being limited by the process, the problem of time dependent dielectric breakdown caused by the short distance between the conductive layer in the medium/high voltage device region and the device in the low voltage device region can be avoided, and the quality of the device can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic top view near a boundary between a medium/high voltage device region and a low-voltage device region in a first embodiment of the present invention.

FIG. 2 is a schematic cross-sectional view of the medium/high voltage device region and the low voltage device region in the first embodiment of the present invention, especially the cross-sectional structure taken along the cross-sectional line A-A′ in FIG. 1.

FIG. 3 shows a schematic top view near a boundary between a medium/high voltage device region and a low-voltage device region in a second embodiment of the present invention.

FIG. 4 is a schematic cross-sectional view of the medium/high voltage device region and the low voltage device region in the second embodiment of the present invention, especially the cross-sectional structure taken along section line B-B′in FIG. 3.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

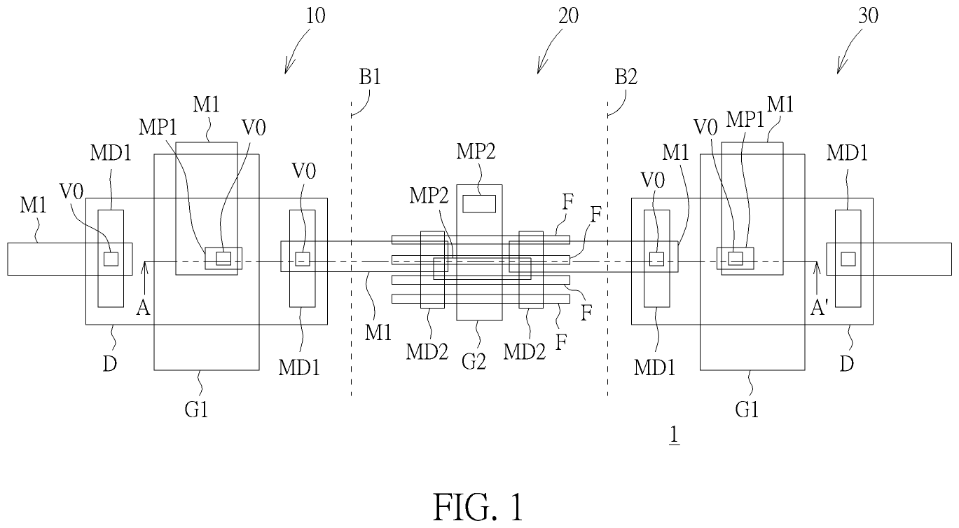

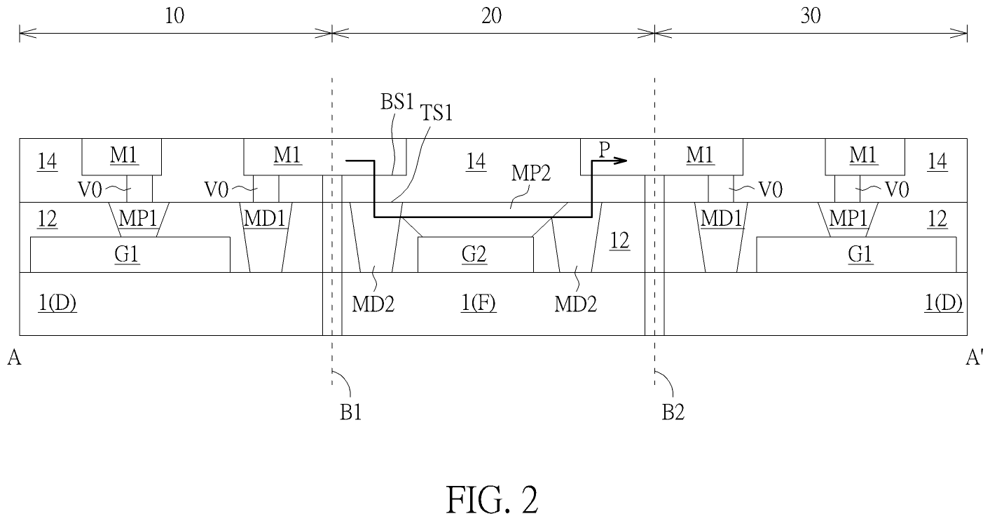

Please refer to FIG. 1 and FIG. 2, in which FIG. 1 shows a schematic top view near a boundary between a medium/high voltage device region and a low voltage device region in the first embodiment of the present invention, and FIG. 2 shows a schematic cross-sectional view near a boundary between a medium/high voltage device region and a low voltage device region in the first embodiment of the present invention, especially the cross-sectional structure taken along section line A-A′ in FIG. 1. As shown in FIG. 1 and FIG. 2, the semiconductor structure 10 of the present invention includes a medium/high voltage device region 10, a low voltage device region 20 and another medium/high voltage device region 30. The low voltage device region 20 is located between the medium/high voltage device region 10 and the medium/high voltage device region 30. There is a boundary line B1 between the medium/high voltage device region 10 and the low voltage device region 20, and a boundary line B2 between the medium/high voltage device region 30 and the low voltage device region 20. Among them, the medium/high voltage device region 10, the medium/high voltage device region 30 and the low voltage device region 20 are different in that the operating voltages of the elements or devices comprised therein are different. Generally speaking, taking a display chip as an example, the low voltage device region 20 includes, for example, a logic operation circuit, and its operating voltage is below 5 volts, preferably within 1.5 volts. On the contrary, the operating voltage of the electronic components comprised in the medium/high voltage device region 10 and the medium/high voltage device region 30 is more than 5 volts, usually more than 10 volts. For example, a driving element in a display chip needs a higher voltage to drive the elements therein, and these elements belong to the medium/high voltage elements of the present invention.

In this embodiment, the medium/high voltage device region 10 and the medium/high voltage device region 30 may have the same or similar structures. Take FIG. 1 as an example, the medium/high voltage device region 10 and the medium/high voltage device region 30 have mutually symmetrical structures, and the elements or devices in them have the same materials and manufacturing methods, so only the medium/high voltage device region 10 and the low voltage device region 20 are mainly described in the following paragraphs, and the description of the medium/high voltage device region 30 is not repeated because it has the same characteristics as the medium/high voltage device region 10.

As mentioned in the prior art, different devices on the same chip may be formed by different precision nano-processes because of their different sizes or applications. In this embodiment, the medium/high voltage devices or other related electronic devices (such as wires or trenches) in the medium/high voltage device region 10 are formed by a process step of 17 nm, for example. On the other hands, various low voltage devices (such as logic operation circuits) in the low voltage device region 20 require a higher nanometer precision, for example, by a process of 14 nm. However, it should be noted that the above 17 nm process and 14 nm processes are only some examples of the present invention, and the present invention is not limited to this.

When the nano-precision of semiconductor process is improved, it means that the size of devices is getting smaller and smaller, and devices can also develop towards three-dimensional structure to increase the density per unit area. In this embodiment, the low voltage device region 20 comprises a plurality of fin structures F to form a three-dimensional structure to reduce the device size. However, the medium/high voltage device region 10 needs to withstand high operating voltage, and the three-dimensional structure such as fin structure is easy to penetrate under high operating voltage, so the plane structure is mainly formed in the medium/high voltage device region 10. That is to say, the top view of the semiconductor structure shown in FIG. 1 can be regarded as the boundary between two regions respectively comprising planar electronic components and regions comprising three-dimensional electronic components, wherein the two regions are formed by different nano-precision processes.

Referring to FIG. 1 and FIG. 2, the medium/high voltage device region 10 includes medium/high voltage devices, such as a substrate 1, on which there are an interlayer dielectric layer 12, a diffusion region D, a gate structure G1, a gate contact MP1 and source/drain contacts MD1. The low voltage device region 20 also includes various devices, such as the substrate 1, the interlayer dielectric layer 12, the fin structures F, the gate structure G2, the gate contact MP2 and the source/drain contacts MD2. As shown in FIG. 2, the gate structure G1, the gate structure G2, the gate contact MP1, the gate contact MP2, the source/drain contact MD1 and the source/drain contact MD2 are all located in an interlayer dielectric layer 12. The material of the interlayer dielectric layer 12 is, for example, silicon oxide, silicon nitride or silicon oxynitride, but not limited thereto. In addition, in this embodiment, the top surfaces of the gate contact MP1 and the source/drain contacts MD1 located in the medium/high voltage device region 10 are aligned with the top surfaces of the gate contact MP2 and the source/drain contacts MD2 located in the low voltage device region 20, but the present invention is not limited to this.

In more detail, taking the formation of high voltage transistor as an example, as shown in FIGS. 1 and 2, high voltage transistors are formed in the medium/high voltage device region 10 and the medium/high voltage device region 30, and these two high voltage transistors can be regarded as two independent elements. The low voltage device region 20 between the medium/high voltage device region 10 and the medium/high voltage device region 30 can be used as the peripheral region of the medium/high voltage device region to accommodate some dummy patterns, reduce exposure problems caused by pattern density differences, or form low voltage electronic elements in the low voltage device region 20, all of which are within the scope of the present invention.

In this embodiment, the substrate 1 is, for example, a silicon substrate, and the diffusion region D in the medium/high voltage device region 10 and the fin structure F in the low voltage device region 20 are made of, for example, silicon, which are part of the substrate 1. The diffusion region D is a planar structure, while the fin structure F is a three-dimensional structure. The gate structures G1 and G2, such as polysilicon gates or metal gates, span the diffusion region D and the fin structure F, and form various semiconductor devices. Taking this embodiment as an example, the gate structure G1 spans the diffusion region D in the medium/high voltage device region 10 to form a high voltage transistor structure. In addition, in this embodiment, the gate structure G2 also spans the fin structure F in the low voltage device region 20. As mentioned above, the gate structure G2 formed in the low voltage device region 20 can be used as the dummy pattern of the gate structure G1 of the medium/high voltage device region 10 to reduce the pattern density difference between different regions. Or in other embodiments, the gate structure G2 in the low voltage device region 20 can be used to form other electronic devices instead of being used as the dummy pattern of the gate structure G1, which is also within the scope of the present invention.

The materials of the gate contact MP1, the gate contact MP2, the source/drain contact MD1 and the source/drain contact MD2 are, for example, metals such as tungsten, cobalt, copper, aluminum, gold, silver, etc, but not limited thereto. The gate contact MP1 is located in the medium/high voltage device region 10, and the gate contact MP2 is located in the low voltage device region 20, which are used to electrically connect the gate structures G1 and G2 and other subsequent wires, so the gate contacts MP1 and MP2 are located above the gate structures G1 and G2 respectively. The source/drain contacts MD1 are located on the diffusion region D for connecting the source/drain region of the high voltage transistor, and the source/drain contacts MD2 are located on the fin structure F. The gate contacts MP1 and MP2 and the source/drain contacts MD1 and MD2 are used to connect other circuit layers formed subsequently.

It is worth noting that as the size of semiconductor devices is getting smaller and smaller, the sizes of the above-mentioned devices including gate structures G1 and G2, gate contacts MP1 and MP2, and source/drain contacts MD1 and MD2 are also reduced. In this case, the difficulty of the overlapping alignment step of the gate contact MP1 and the gate structure G1 will also increase. In other words, since the gate contact MP1 needs to be accurately overlapped with the gate structure G1 to be electrically connected with each other, as the sizes of the gate contact MP1 and the gate structure G1 become smaller and smaller, this overlapping step will become more and more difficult. On the other hand, the size of the gate contact MP1 (horizontal dimension in cross section) is close to the exposure limit of the current machine, so it is difficult to make the gate contact MP1 to a sufficient height, because this will lead to an excessive aspect ratio of the gate contact MP1, resulting in manufacturing defects (for example, the gate contact MP1 is broken due to the difficulty in gap filling). In this embodiment, the height of the gate contact MP1 can only be made to about 450 angstroms under the process of 17 nm. If the height of the gate contact MP1 is too high, it will easily lead to the above-mentioned problem that the gate contact MP1 is broken due to insufficient gap filling due to too large aspect ratio. Explain with the actual process, in other processes with larger dimensions, such as 22 nm or 28 nm, after the gate contact MP1 is formed on the gate structure G1, the first conductive layer M1 can be directly formed to connect with the gate contact MP1. However, when the process is reduced to less than 17 nm, the height of the gate contact MP1 is limited, so the first conductive layer M1 cannot be directly formed on the gate contact MP1, otherwise the first conductive layer M1 will directly contact other adjacent contact structures such as the source.

In order to solve the above problems, in this embodiment, in addition to forming the gate contact MP1, a via structure V0 is additionally formed on the gate contact MP1 and the source/drain contacts MD1, and then a first conductive layer M1 is formed above the via structure V0. The materials of the via structure V0 and the first conductive layer M1 described here are, for example, metals such as tungsten, cobalt, copper, aluminum, gold, silver, etc., but are not limited thereto. The via structure V0 and the first conductive layer M1 are used to connect the lower high voltage transistor element to other elements formed above. That is, in order to overcome the problem of insufficient height of the gate contact MP1, the original single contact structure is replaced by two overlapping contact structures (namely, the gate contact MP1 and the via structure V0). In addition, the via structure V0 and the first conductive layer M1 are located in a dielectric layer 14, for example, an ultra-low dielectric constant (ULK) layer, and its dielectric constant is preferably lower than 2.9, but not limited to this. Generally, the commonly used ULK materials may include Black Diamond (low dielectric constant material of carbon-doped silicon oxide introduced by Applied Materials Company), MSQ (methylsilsesquioxane), porous SiLK (a low dielectric constant material developed by Dow Chemical), etc., but are not limited to this.

However, the height of the via structure V0 is also limited by the process. For example, in this embodiment, the height of the via structure V0 is about 480 angstroms, and the first conductive layer M1 is formed on the via structure V0, and a part of the first conductive layer M1 extends laterally from the medium/high voltage device region 10 into the low voltage device region 20, so the distance between the bottom surface BS1 of the first conductive layer M1 in the low voltage device region 20 and the top surface TS1 of the source/drain contact MD1 below is only about 480 angstroms (same as the height of via structure V0). In this case, the applicant found another problem, that is, when the medium/high voltage semiconductor device is operating, it may produce a time dependent dielectric breakdown (TDDB) effect, that is, the current may penetrate through the dielectric layer 14 and flow to the source/drain contacts MD below, resulting in that the circuit cannot be connected to the expected device. For example, in this embodiment, as shown in FIG. 2, if the source/drain contacts MD2 in the low voltage device region 20 is connected to the gate contact MP2, then the current may flow from the medium/high voltage semiconductor device in the medium/high voltage device region 10 to the device in the low voltage device region 20 and then to another medium/high voltage semiconductor device in the medium/high voltage device region 30 through the path P, so the medium/high voltage semiconductor devices in two different regions will be influenced by each other, causing electrical errors and device damage.

It should be noted that the device pattern located in the low voltage device region 20 in FIG. 1 of the present invention may be changed as required, and is not limited to the structure shown in FIG. 1. Although the source/drain contacts MD2 are designed to be connected to the gate contact MP2 in FIG. 1, this pattern structure is only one example of the present invention. In other embodiments of the present invention, other devices such as transistors may be formed in the low voltage device region 20, and the source/drain contacts MD2 and the gate contact MP2 are not in contact with each other. However, even if the source/drain contacts MD2 and the gate contact MP2 are not in contact with each other, the current in the medium/high voltage device region 10 may still pass through the first conductive layer M1 and penetrate the dielectric layer 14 and then be transmitted to the devices in the low voltage device region 20, and the device quality in the low voltage device region will be affected.

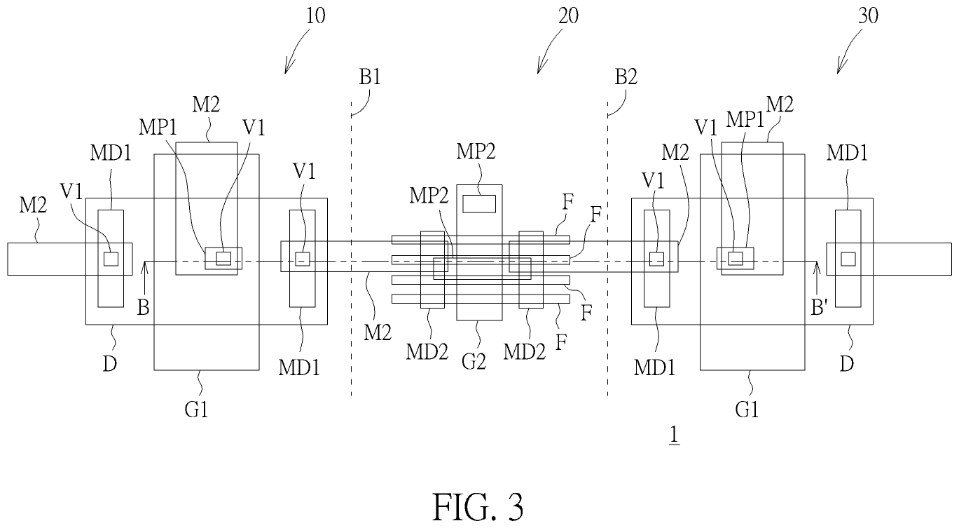

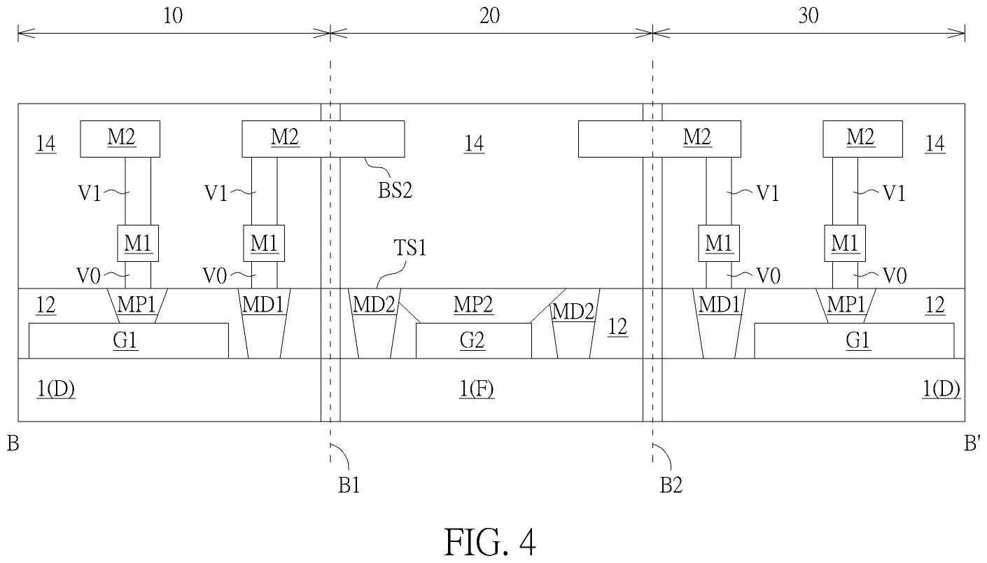

The applicant found that the structure of FIG. 2 has the above-mentioned probability of possible defects, especially at the boundary of the medium/high voltage device region and the low voltage device region. Therefore, in order to improve the structure of FIG. 2, the applicant provides another structure. Please refer to FIG. 3 and FIG. 4. FIG. 3 shows a schematic top view near a boundary between a medium/high voltage device region and a low-voltage device region in a second embodiment of the present invention, and FIG. 4 is a schematic cross-sectional view of the medium/high voltage device region and the low voltage device region in the second embodiment of the present invention, especially the cross-sectional structure taken along section line B-B′in FIG. 3. In this embodiment, since it is known that the bottom surface BS1 of the first conductive layer M1 is too close to the top surface TS1 of the source/drain contact MD below, the problem of time dependent dielectric breakdown (TDDB) may occur, in this embodiment, the first conductive layer M1 is not extended to the low voltage device region 20. The via structure V1 and the second conductive layer M2 are formed on the first conductive layer M1. If the device needs to extend into the low voltage device region 20 in configuration, the second conductive layer M2 extends into the range of the low voltage device region 20. In other words, the distance between the bottom surface BS2 of the second conductive layer M2 and the top surface TS1 of the second source/drain contacts MD2 below is far enough, at least more than 700 angstroms, so it is not easy to cause the problem that the above-mentioned time dependent dielectric breakdown causes the current to flow to the devices in the low voltage device region 20 unexpectedly. It can effectively solve the problem of time dependent dielectric breakdown at the boundary of medium/high voltage device region and low voltage device region under the process of 17 nm, and improve the quality of the device.

Based on the above description and drawings, the present invention provides a semiconductor structure, which comprises a substrate 1, on which a first medium/high voltage device region 10 and a low voltage device region 20 are defined adjacent to each other, the first medium/high voltage device region 10 comprises a first gate contact MP1 and first source/drain contacts MD1, and the low voltage device region 20 comprises two second source/drain contacts MD2 and a second gate contact MP2. The second gate contact MP2 is located between and directly contacts two second source/drain contacts MD2, a first conductive layer M1 is located in the first medium/high voltage device region 10 and electrically connected to the first gate contact MP1 or the first source/drain contact MD1, wherein the first conductive layer M1 does not extend into the low voltage device region 20, a second conductive layer M2 located above the first conductive layer M1 and spanning the first medium/high voltage device region 10 and the low voltage device region 20, a the second conductive layer M2 is electrically connected with the first conductive layer M1.

In some embodiments of the present invention, the first medium/high voltage device region 10 further includes a first gate structure G1 spanning a diffusion region D, wherein the first gate contact MP1 is electrically connected to the first gate structure G1, and the first source/drain contact MD1 is electrically connected to the diffusion region D.

In some embodiments of the present invention, the low voltage device region 20 further includes a second gate structure G2 spanning a plurality of fin structures F, and the second source/drain contacts MD2 are electrically connected to the plurality of fin structures F.

In some embodiments of the present invention, a top surface of the second gate contact MP2 is aligned with the top surfaces of the two second source/drain contacts MD2.

In some embodiments of the present invention, in the low voltage device region 20, the conductive material layer is not included at the same level as the first conductive layer M1 (which means that the first conductive layer M1 will not extend to the low voltage device region 20, and other wire/conductive materials will not be included in the low voltage device region 20 at the same level as the first conductive layer M1).

In some embodiments of the present invention, the second conductive layer M2 extends into the low voltage device region 20 and is located directly above at least one second source/drain contact MD2.

In some embodiments of the present invention, in the low voltage device region 20, the distance between a bottom surface BS2 of the second conductive line layer M2 and a top surface TS1 of the second source/drain contact MD2 in a vertical direction is greater than 700 angstroms (according to the applicant's experiment, time dependent dielectric breakdown can be avoided when the distance is greater than 700 angstroms).

In some embodiments of the present invention, a second medium/high voltage device region 30 is further included, wherein the low voltage device region 20 is located between the first medium/high voltage device region 10 and the second medium/high voltage device region 30, and the low voltage device region 20 is directly adjacent to the first medium/high voltage device region 10 and the second medium/high voltage device region 30.

In some embodiments of the present invention, the elements comprised in the second medium/high voltage device region 30 and the elements comprised in the first medium/high voltage device region 10 are arranged in mirror images (which mean the symmetrical arrangement of these two patterns).

In some embodiments of the present invention, the first source/drain contact MD1 in the first medium/high voltage device region 10 is directly adjacent to one of the second source/drain contacts MD2 in the low voltage device region 20 (that is, no other elements are included between the first source/drain contact MD1 and the second source/drain contact MD2 on both sides of the boundary line B1 in cross section).

The invention also provides a method for manufacturing a semiconductor structure, which comprises providing a substrate 1, wherein a first medium/high voltage device region 10 and a low voltage device region 20 are defined on the substrate 1, the first medium/high voltage device region 10 comprises a first gate contact MP1 and a first source/drain contact MD1, and the low voltage device region 20 comprises two second source/drain contacts MD2 and a second gate contact MP2. The second gate contact MP2 is located between two second source/drain contacts MD2, and directly contacts the two second source/drain contacts MD2 to form a first conductive layer M1 located in the first medium/high voltage device region 10 and electrically connected with the first gate G1 contact or the first source/drain contact MD1, wherein the first conductive layer M1 does not extend into the low voltage device region 20, and a second conductive layer M2 is formed on the first conductive layer M1, and the second conductive layer M2 spans the first medium/high voltage device region 10 and the low voltage device region 20, wherein the second conductive layer M2 is electrically connected with the first conductive layer M1.

To sum up, the applicant found that with the development of technology, the size of semiconductor devices is getting smaller and smaller, especially at the boundary of medium/high voltage device regions and low voltage device regions, various structural problems are easy to occur. For example, in the conventional 22 nm or 28 nm process, time dependent dielectric breakdown will not occur at the boundary of the medium/high voltage device region and the low voltage device region. However, as the process progresses below 17 nm, the conductive layer in the medium/high voltage device region is too close to the device in the low voltage device region, which may affect the quality of other devices due to time dependent dielectric breakdown. Therefore, the present invention aims at solving this problem, and specifically designs a semiconductor structure so that the first conductive layer in the medium/high voltage device region does not extend to the low voltage device region, and the second conductive layer in the medium/high voltage device region extends to the low voltage device region. Therefore, without changing the process conditions and being limited by the process, the problem of time dependent dielectric breakdown caused by the short distance between the conductive layer in the medium/high voltage device region and the device in the low voltage device region can be avoided, and the quality of the device can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising:
a substrate, on which a first medium/high voltage device region and a low voltage device region are defined adjacent to each other, wherein the first medium/high voltage device region comprises a first gate contact and a first source/drain contact, and the low voltage device region comprises two second source/drain contacts and a second gate contact, wherein the second gate contact is located between the two second source/drain contacts and directly contacts the two second source/drain contacts;
a first conductive layer located in the first medium/high voltage device region and electrically connected to the first gate contact or the first source/drain contact, wherein the first conductive layer does not extend into the low voltage device region; and
a second conductive layer located above the first conductive layer and spanning the first medium/high voltage device region and the low voltage device region, wherein the second conductive layer is electrically connected with the first conductive layer.

2. The semiconductor structure according to claim 1, wherein the first medium/high voltage device region further comprises a first gate structure spanning a diffusion region, wherein the first gate contact is electrically connected to the first gate structure, and the first source/drain contact is electrically connected to the diffusion region.

3. The semiconductor structure according to claim 1, wherein the low voltage device region further comprises a second gate structure spanning a plurality of fin structures, and the second source/drain contact is electrically connected with the plurality of fin structures.

4. The semiconductor structure according to claim 1, wherein a top surface of the second gate contact is aligned with the top surfaces of the two second source/drain contacts.

5. The semiconductor structure according to claim 1, wherein a conductive material layer is not included in the low voltage device region at the same level as the first conductive layer.

6. The semiconductor structure according to claim 1, wherein the second conductive layer extends into the low voltage device region and is located directly above at least one second source/drain contact.

7. The semiconductor structure according to claim 6, wherein the distance between a bottom surface of the second conductive layer and a top surface of the second source/drain in a vertical direction is greater than 700 angstroms in the low voltage device region.

8. The semiconductor structure according to claim 1, further comprising a second medium/high voltage device region, wherein the low voltage device region is located between the first medium/high voltage device region and the second medium/high voltage device region, and the low voltage device region is directly adjacent to the first medium/high voltage device region and the second medium/high voltage device region.

9. The semiconductor structure according to claim 8, wherein the devices comprised in the second medium/high voltage device region and the devices comprised in the first medium/high voltage device region are arranged in mirror images with each other.

10. The semiconductor structure according to claim 1, wherein the first source/drain contact in the first medium/high voltage device region is directly adjacent to one of the second source/drain contacts in the low voltage device region when viewed from a cross section.

11. A manufacturing method of a semiconductor structure, comprising:
providing a substrate on which a first medium/high voltage device region and a low voltage device region are defined adjacent to each other, wherein the first medium/high voltage device region comprises a first gate contact and a first source/drain contact, and the low voltage device region comprises two second source/drain contacts and a second gate contact, wherein the second gate contact is located between the two second source/drain contacts and directly contacts the two second source/drain contacts;
forming a first conductive layer located in the first medium/high voltage device region and electrically connected to the first gate contact or the first source/drain contact, wherein the first conductive layer does not extend into the low voltage device region; and
forming a second conductive layer above the first conductive layer and spanning the first medium/high voltage device region and the low voltage device region, wherein the second conductive layer is electrically connected with the first conductive layer.

12. The method for manufacturing a semiconductor structure according to claim 11, wherein the first medium/high voltage device region further comprises a first gate structure spanning a diffusion region, wherein the first gate contact is electrically connected to the first gate structure, and the first source/drain contact is electrically connected to the diffusion region.

13. The method for manufacturing a semiconductor structure according to claim 11, wherein the low voltage device region further comprises a second gate structure spanning a plurality of fin structures, and the second source/drain contact is electrically connected to the plurality of fin structures.

14. The method for manufacturing a semiconductor structure according to claim 11, wherein a top surface of the second gate contact is aligned with the top surfaces of the two second source/drain contacts.

15. The method for manufacturing a semiconductor structure according to claim 11, wherein a conductive material layer is not included at the same level as the first conductive layer in the low voltage device region.

16. The manufacturing method of a semiconductor structure according to claim 11, wherein the second conductive layer extends into the low voltage device region and is located directly above at least one second source/drain contact.

17. The method for manufacturing a semiconductor structure according to claim 16, wherein the distance between a bottom surface of the second conductive layer and a top surface of the second source/drain in a vertical direction is greater than 700 angstroms in the low voltage device region.

18. The method for manufacturing a semiconductor structure according to claim 11, further comprising defining a second medium/high voltage device region, wherein the low voltage device region is located between the first medium/high voltage device region and the second medium/high voltage device region, and the low voltage device region is directly adjacent to the first medium/high voltage device region and the second medium/high voltage device region.

19. The method for manufacturing a semiconductor structure according to claim 18, wherein the devices comprised in the second medium/high voltage device region and the devices comprised in the first medium/high voltage device region are arranged in mirror images.

20. The method for manufacturing a semiconductor structure according to claim 11, wherein the first source/drain contact in the first medium/high voltage device region is directly adjacent to one of the second source/drain contacts in the low voltage device region when viewed from a cross section.
